(19) United States
(12) Patent Application Publication
(10) Pub. No.: US 2022/0309203 A1
(43) Pub. Date: Sep. 29, 2022

(54) ARTIFICIAL INTELLIGENCE-BASED AUTOMATIC GENERATION METHOD FOR URBAN ROAD NETWORK

(71) Applicant: SOUTHEAST UNIVERSITY, Nanjing, Jiangsu (CN)

(72) Inventors: Junyan YANG, Nanjing, Jiangsu (CN); Geyang XIA, Nanjing, Jiangsu (CN); Xiao ZHU, Nanjing, Jiangsu (CN); Beixiang SHI, Nanjing, Jiangsu (CN); Zhengcheng ZHANG, Nanjing, Jiangsu (CN); Xiaofang YANG, Nanjing, Jiangsu (CN)

(21) Appl. No.: 17/616,293

(22) PCT Filed: Oct. 28, 2020
(86) PCT No.: PCT/CN2020/124318

§ 371 Date: Dec. 3, 2021

(30) Foreign Application Priority Data
Sep. 4, 2020 (CN) 202010923489.5

(51) Int. Cl. G06F 30/13; G06N 3/08; G06N 3/04; G06F 30/27; G06Q 50/26

(52) U.S. Cl. CPC G06F 30/13; G06N 3/088; G06N 3/0454; G06F 30/27; G06Q 50/26

(57) ABSTRACT

The present invention discloses an artificial intelligence (AI)-based automatic generation method for an urban road network. According to the method, an anchor point distribution model is constructed by means of machine learning. Anchor points are distributed within a planning range where a boundary is a secondary trunk road. A road center line layout scheme set is generated by means of rectangular expansion. A feasible scheme set is screened out based on a rule base translated from specifications related to urban planning road, a road network scheme set is further automatically generated, and finally, a scheme is outputted to a two-dimensional interaction display device for simulated display. The present invention realizes a road network design by using a combination of machine learning and rules of the urban planning field. The present invention provides a simple and efficient automatic generation method for an urban road network. By means of the present invention, a plurality of schemes can be generated within a short time, which provide an efficient and visualized reference for the design and the practice of AI urban planning.

### TECHNICAL FIELD

The present invention relates to an automatic generation method for an urban road network, and specifically, to an artificial intelligence (AI)-based automatic generation method for an urban road network.

### BACKGROUND

Continuous development of AI technologies brings unprecedented impact to the field of urban planning and design. Applying AI to the whole process work, such as survey and analysis, design and research, and management and monitoring of urban planning becomes a key direction of current and future urban planning and research. At a design phase, the design of an urban road network is primary, and is a basis of the design of street blocks and buildings. An urban space is complex and diverse, a road network shape and urban elements, such as natural landscapes and land usage influence and restrict each other. Therefore, the design of the urban road network has a series of uncertain factors, and is still challenging.

In a conventional automatic generation method for an urban road network, existing roads and streets are generated in a computer based on aerially photographed and remotely sensed images or vehicle tracks. However, the method is merely a reproduction of a real road network, and has a limited effect for new urban districts lacking roads. Another method is based on image learning. In the method, adversarial training is performed based on rules obtained by learning massive road network samples, to generate a network model, and a road network is generated in a plot having a strictly regulated dimension. However, in the method, a model training speed is low, fitting between a generated result and a real road network is insufficient, the costs for manually screening out a feasible road network are relatively high, and the like.

### SUMMARY

The present invention is intended to provide an AI-based automatic generation method for an urban road network. The automatic generation method for an urban road network of the present invention has the following advantages. Process efficiency: According to the method, a feasible range of an urban road network scheme is set. By means of the method, a plurality of schemes can be simultaneously generated within a short time, so that manpower costs are reduced, and the design efficiency is enhanced. System simulation: According to the method, an interpretable generative adversarial network (infoGAN) is applied to construct a road network rule base based on specifications related to urban road planning, and a road network scheme set is automatically generated based on the road network rule base. By means of the method, the fitting between the scheme set and the real road network is increased, and the quality of the automatically generated scheme set is guaranteed. Achievement accessibility: The achievement of the method is simulated and displayed by using a two-dimensional interaction device, facilitating communication between an urban planning professionals and managers.

The objective of the present invention may be achieved by the following technical solutions:

An AI-based automatic generation method for an urban road network includes the following steps:

S1: collecting, by a data acquisition and input module, two-dimensional vector data from an urban open-source data platform by using an unmanned aerial vehicle (UAV), and inputting the two-dimensional vector data to a geographic information platform;

S2: collecting, by a machine learning module, branch network data from the open-source data platform, to construct an urban branch network sample library; generating a corresponding anchor point distribution library by using centroids of rectangles formed by branches as anchor points; converting a vector image in the anchor point distribution sample library to a bitmap image, to construct an anchor point distribution machine learning sample library having a unified dimension; and performing adversarial training on an anchor point distribution model based on a generative adversarial network;

S3: inputting, by a rule base construction module, the specification for spacing range of urban branch, the specification for boundary line of urban road, and the specification for chamfering of urban road in the Code for Transport Planning on Urban Road to the geographic information platform, and constructing a rule base;

S4: generating and distributing, by a scheme set generation module, the anchor points within a planning range by using the anchor point distribution model obtained by the machine learning module, to generate an anchor point distribution scheme set; generating a corresponding Thiessen polygon distribution scheme set according to anchor points of each scheme in the anchor point distribution scheme set; replacing the anchor points in Thiessen polygons in the Thiessen polygon distribution scheme set with centroids of the polygons as new anchor points, to generate a new anchor point distribution scheme set; generating corresponding road center line layout scheme sets by means of rectangular expansion by using the new anchor points in the new anchor point distribution scheme set as a center; and screening out a feasible road center line layout scheme set by using the rule base of the Code for Transport Planning on Urban Road, generating road network schemes from schemes in the feasible road center line layout scheme set according to the rule base of the Code for Transport Planning on Urban Road and output the road network schemes, and generating a road network scheme set; and

S5: outputting, by a man-machine interaction display module, the road network scheme set to a two-dimensional interaction display device, where the two-dimensional interaction display device specifically generates scheme drawings, simulates scheme effects, and displays various scheme indexes.

Further, in step S1, a boundary line of the planning range is a secondary trunk road, only a branch network is generated within the planning range, and the collected two-dimensional vector data within the planning range includes information about shapes and dimensions of polygonal plots having closed outlines.

Further, the operation of constructing the urban branch network sample library specifically includes collecting branch road network data of Chinese cities from the open-source data platform, and inputting the branch road network data to the geographic information platform, a boundary of a sample planning range is a secondary trunk road, a branch network is formed within the planning range, and a sample quantity is 10000.

Further, the operation of constructing the anchor point distribution machine learning sample library having a unified dimension specifically includes converting the vector image of the anchor point distribution sample library to a bitmap image at a proportional scale of 1:2000, and having a resolution of 100 dpi and a dimension of 300 mm*300 mm, so as to generate the anchor point distribution machine learning sample library, where a sample quantity is 10000.

Further, the operation of performing adversarial training on the anchor point distribution model based on the generative adversarial network in step S2 specifically includes: constructing a generative network by using white gaussian noise as input data and an anchor point automatic distribution image as output data; designing a loss function by using the anchor point automatic distribution image and an anchor point distribution machine learning sample image as the input data, so as to construct a determination network, where the generative network and the determination network are convolutional neural networks (CNN); and performing iterative training on the generative network and the determination network, so that the anchor automatic distribution image gradually approximates the anchor point distribution machine learning sample image.

Further, the operation of constructing the rule base in step S3 includes constructing index controls according to the Code for Transport Planning on Urban Road and the specification for chamfer radius of road;

TABLE 1
Index controls for different branch network rules

| Control item | Control parameter range | |
|---|---|---|
| Branch network spacing | 150-250 | m |
| Width of boundary line of road | 12-15 | m |
| Internal chamfer of branch network | 10-15 | m |
| Chamfer of branch and external | 20-25 | m |
| secondary trunk road | | |

Further, in step S4, the road center line layout scheme is a corresponding road center line layout scheme generated by means of rectangular expansion by using the new anchor points as a center, and a specific operation includes: controlling a new anchor point distribution scheme to expand in a square shape in four orthogonal directions of the new anchor point distribution scheme at a same speed by using each new anchor point as a center, when expansion sides of two adjacent anchor points come into contact with each other, or when the expansion sides all exceed the planning range, stopping expansion of the expansion sides, and still expanding other expansion sides, until all boundaries stop expanding, so as to generate rectangles of a quantity is same as a quantity of the anchor points; and arranging sides of the rectangles to form a road center line layout, and deleting sides of the rectangles that are outside the planning range or overlapping the planning range, and arranging sides of the rectangles that are inside the planning range into unique non-overlapping line segments.

Further, the operation of screening out the feasible road center line layout scheme set specifically includes determining whether lengths of all road center line segments in the road center line layout scheme generated by means of rectangular expansion are within a range of 150-250 m, if no, discarding the scheme, or if yes, outputting the scheme to the feasible road center line layout scheme set.

Further, the operation of generating the road network scheme set specifically includes expanding the feasible road center line layout scheme by 6-7.5 m toward two sides from a center line, to form a road boundary line having a width of 12-15 m, generating a road boundary line chamfer of 10-15 m at an intersection of internal branches, generating a road boundary line chamfer of 20-25 m at an intersection of a boundary branch and a secondary trunk road, and integrating road network schemes after the boundary line and chamfer are generated, to generate the road network scheme set.

Further, the simulation and the display of the scheme effects mean that an examiner selects a required road network scheme from a road network scheme library by using an operation rod and displays a scheme drawing, a scheme effect simulation diagram, and various scheme indexes on a display device having a dimension more than 55 inches and a resolution of 1920×1080; the scheme effect simulation diagram means mapping roadways and sidewalks by using modeling software on a basis of a road planar view within a planning range, where the roadways are mapped with asphalt textures, and the sidewalks are mapped with bricks, rendering a road network model, and combining a model render with a real scene photographed by a UAV by using image editing software, to form a scheme effect simulation diagram for displaying; and the various scheme indexes include a road grade, a width of a road boundary line, a road boundary line chamfer, a side length and an area of a street block formed by roads, a density of a branch network in a planning range, and a proportion of crossroad nodes to all intersection nodes.

Beneficial effects of the present invention are as follows:

1. The automatic generation method for an urban road network of the present invention has process efficiency. According to the method, a feasible range of an urban road network scheme is set. By means of the method, a plurality of schemes can be simultaneously generated within a short time, so that manpower costs are reduced, and the design efficiency is enhanced.

2. The automatic generation method for an urban road network of the present invention has system simulation. According to the method, an interpretable generative adversarial network (infoGAN) is applied to construct a road network rule base based on specifications related to urban road planning, and a road network scheme set is automatically generated based on the road network rule base. By means of the method, the fitting between the scheme set and the real road network is increased, and the quality of the automatically generated scheme set is guaranteed.

3. The automatic generation method for an urban road network of the present invention has achievement accessibility. The achievement of the method is simulated and displayed by using a two-dimensional interaction device, facilitating communication between an urban planning professionals and managers.

### BRIEF DESCRIPTION OF THE DRAWINGS

The following further describes the present invention in detail with reference to the accompanying drawings.

FIG. 1 is a flowchart of a generation method according to the present invention.

FIG. 2 is a schematic diagram of a planning range for automatic road generation according to the present invention.

FIG. 3 is a schematic diagram of screening of a road center line layout scheme according to the present invention.

FIG. 4 is a diagram of an automatically generated road scheme according to the present invention.

### DETAILED DESCRIPTION

The technical solutions of the embodiments of the present invention are clearly and completely described below with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention without creative efforts shall fall within the protection scope of the present invention.

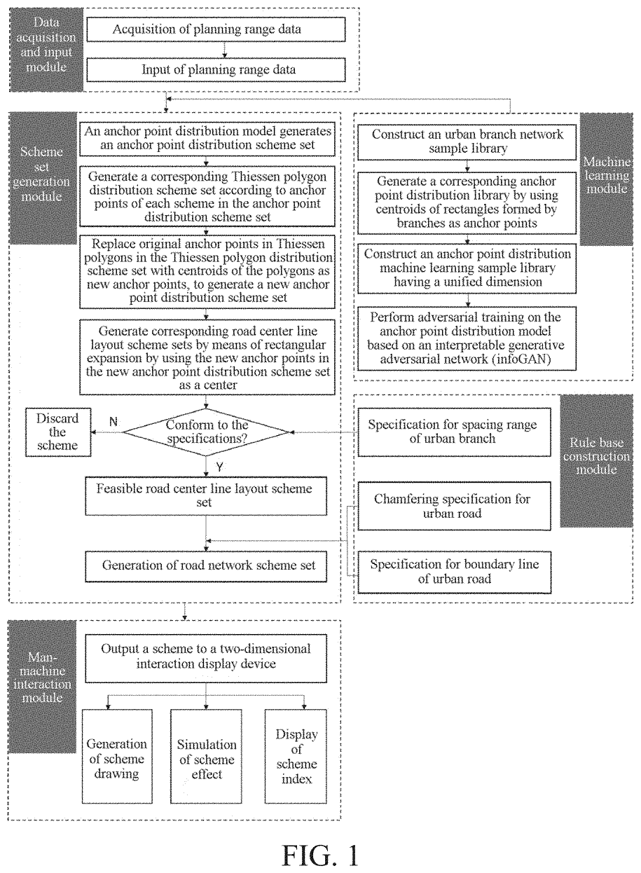

As shown in FIG. 1, an AI-based automatic generation method for an urban road network includes the following steps.

S1: A data acquisition and input module collects two-dimensional vector data from an urban open-source data platform by using a UAV camera loaded with a lens having a resolution of 1920*1080, and inputs the two-dimensional vector data to a geographic information platform.

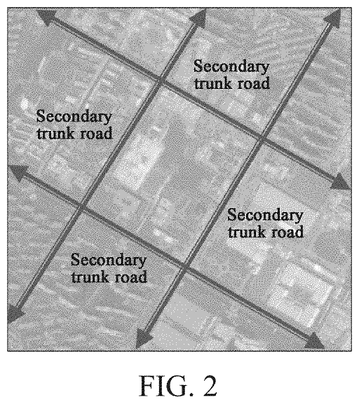

As shown in FIG. 2, a boundary line of the planning range is a secondary trunk road, and only a branch network is generated within the planning range. The collected two-dimensional vector data within the planning range includes information about geographic coordinates, shapes, and dimensions of polygonal plots having closed outlines.

S2: A machine learning module collects branch network data from the open-source data platform, to construct an urban branch network sample library; generates a corresponding anchor point distribution library by using centroids of rectangles formed by branches as anchor points; converts a vector image in the anchor point distribution sample library to a bitmap image, to construct an anchor point distribution machine learning sample library having a unified dimension; and performs adversarial training on an anchor point distribution model based on an interpretable generative adversarial network (infoGAN).

The operation of constructing the urban branch network sample library specifically includes collecting branch road network data of Chinese cities from the open-source data platform, and inputting the branch road network data to the geographic information platform. A boundary of a sample planning range is a secondary trunk road, a branch network is formed within the planning range, and a sample quantity is 10000.

The operation of constructing the anchor point distribution machine learning sample library having a unified dimension specifically includes converting the vector image of the anchor point distribution sample library to a bitmap image at a proportional scale of 1:2000, and having a resolution of 100 dpi and a dimension of 300 mm*300 mm, so as to generate the anchor point distribution machine learning sample library, where a sample quantity is 10000.

The operation of performing adversarial training on the anchor point distribution model based on the interpretable generative adversarial network (infoGAN) specifically includes: constructing a generative network by using white gaussian noise as input data and an anchor point automatic distribution image as output data; designing a loss function by using the anchor point automatic distribution image and an anchor point distribution machine learning sample image as the input data, so as to construct a determination network, where the generative network and the determination network are convolutional neural networks (CNN); and performing iterative training on the generative network and the determination network, so that the anchor automatic distribution image gradually approximates the anchor point distribution machine learning sample image.

S3: A rule base construction module inputs the specification for spacing range of urban branch, the specification for boundary line of urban road, and the specification for chamfering of urban road in the Code for Transport Planning on Urban Road to the geographic information platform, and constructs a rule base.

Index controls are constructed according to the Code for Transport Planning on Urban Road and the specification for chamfer radius of road.

TABLE 1
Index controls for different branch network rules

| Control item | Control parameter range | |
|---|---|---|
| Branch network spacing | 150-250 | m |
| Width of boundary line of road | 12-15 | m |
| Internal chamfer of branch network | 10-15 | m |
| Chamfer of branch and external | 20-25 | m |
| secondary trunk road | | |

S4: A scheme set generation module generates and distributes the anchor points within a planning range by using the anchor point distribution model obtained by the machine learning module, to generate an anchor point distribution scheme set; generates a corresponding Thiessen polygon distribution scheme set according to anchor points of each scheme in the anchor point distribution scheme set; replaces the anchor points in Thiessen polygons in the Thiessen polygon distribution scheme set with centroids of the polygons as new anchor points, to generate a new anchor point distribution scheme set; generates corresponding road center line layout scheme sets by means of rectangular expansion by using the new anchor points in the new anchor point distribution scheme set as a center; and screens out a feasible road center line layout scheme set by using the rule base of the Code for Transport Planning on Urban Road, generates road network schemes from schemes in the feasible road center line layout scheme set according to the rule base of the Code for Transport Planning on Urban Road and output the road network schemes, and generates a road network scheme set.

The operation of generating the road center line layout scheme by means of rectangular expansion by using the new anchor points as a center specifically includes: controlling a new anchor point distribution scheme to expand in a square shape in four orthogonal directions of the new anchor point distribution scheme at a same speed by using each new anchor point as a center, when expansion sides of two adjacent anchor points come into contact with each other, or when the expansion sides all exceed the planning range, stopping expansion of the expansion sides, and still expanding other expansion sides, until all boundaries stop expanding, so as to generate rectangles of a quantity is same as a quantity of the anchor points; and. arranging sides of the rectangles to form a road center line layout, and deleting sides of the rectangles that are outside the planning range or overlapping the planning range, and arranging sides of the rectangles that are inside the planning range into unique non-overlapping line segments.

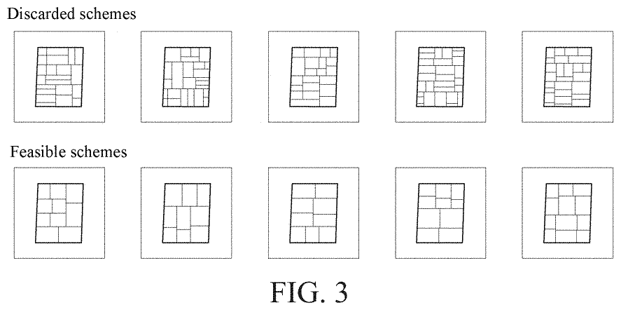

The operation of screening out the feasible road center line layout scheme set specifically includes determining whether lengths of all road center line segments in the road center line layout scheme generated by means of rectangular expansion are within a range of 150-250 m, if no, discarding the scheme, or if yes, outputting the scheme to the feasible road center line layout scheme set, as shown in FIG. 3.

The operation of generating the road network scheme set specifically includes expanding the feasible road center line layout scheme by 6-7.5 m toward two sides from a center line, to form a road boundary line having a width of 12-15 m, generating a road boundary line chamfer of 10-15 m at an intersection of internal branches, generating a road boundary line chamfer of 20-25 m at an intersection of a boundary branch and a secondary trunk road, and. integrating road network schemes after the boundary line and chamfer are generated, to generate the road network scheme set.

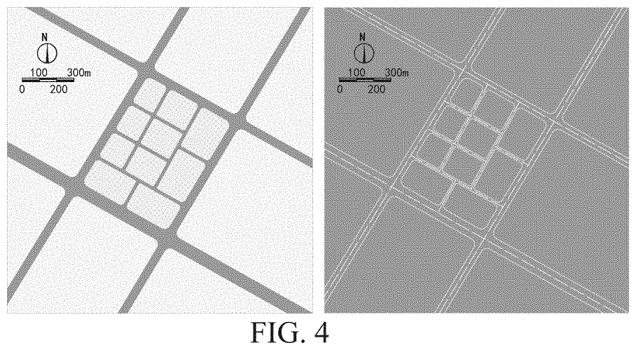

S5: A man-machine interaction display module outputs the road network scheme set to a two-dimensional interaction display device having a dimension more than 55 inches and a resolution of 1920×1080, where the two-dimensional interaction display device specifically generates scheme drawings, simulates scheme effects, and displays various scheme indexes, as shown in FIG. 4.

The simulation and the display of the scheme effects mean that an examiner selects a required road network scheme from a road network scheme library by using an operation rod and displays a scheme drawing, a scheme effect simulation diagram, and various scheme indexes on a display device having a dimension more than 55 inches and a resolution of 1920×1080. The scheme effect simulation diagram means mapping roadways and sidewalks by using modeling software on a basis of a road planar view within a planning range, where the roadways are mapped with asphalt textures, and the sidewalks are mapped with bricks, rendering a road network model, and combining a model render with a real scene photographed by a UAV by using image editing software, to form a scheme effect simulation diagram for displaying. The various scheme indexes include a road grade, a width of a road boundary line, a road boundary line chamfer, a side length and an area of a street block formed by roads, a density of a branch network in a planning range, and a proportion of crossroad nodes to all intersection nodes.

In the descriptions of this specification, a description of a reference term such as “an embodiment”, “an example”, or “a specific example” means that a specific feature, structure, material, or characteristic that is described with reference to the embodiment or the example is included in at least one embodiment or example of the present invention. In this specification, exemplary descriptions of the foregoing terms do not necessarily refer to the same embodiment or example. In addition, the described specific features, structures, materials, or characteristics may be combined in a proper manner in any one or more of the embodiments or examples.

The foregoing displays and describes basic principles, main features, and advantages of the present invention. A person skilled in the art may understand that the present invention is not limited to the foregoing embodiments. Descriptions in the embodiments and this specification merely illustrate the principles of the present invention. Various modifications and improvements are made in the present invention without departing from the spirit and the scope of the present invention, and such modifications and improvements shall fall within the protection scope of the present invention.

What is claimed is:

1. An artificial intelligence (AI)-based automatic generation method for an urban road network, the method comprising:
S1: collecting, by a data acquisition and input module, two-dimensional vector data from an urban open-source data platform by using an unmanned aerial vehicle (UAV), and inputting the two-dimensional vector data to a geographic information platform;
S2: collecting, by a machine learning module, branch network data from the open-source data platform, to construct an urban branch network sample library; generating a corresponding anchor point distribution library by using centroids of rectangles formed by branches as anchor points; converting a vector image in the anchor point distribution sample library to a bitmap image, to construct an anchor point distribution machine learning sample library having a unified dimension; and performing adversarial training on an anchor point distribution model based on a generative adversarial network;
S3: inputting, by a rule base construction module, the specification for spacing range of urban branch, the specification for boundary line of urban road, and the specification for chamfering of urban road in the Code for Transport Planning on Urban Road to the geographic information platform, and constructing a rule base;
S4: generating and distributing, by a scheme set generation module, the anchor points within a planning range by using the anchor point distribution model obtained by the machine learning module, to generate an anchor point distribution scheme set; generating a corresponding Thiessen polygon distribution scheme set according to anchor points of each scheme in the anchor point distribution scheme set; replacing the anchor points in Thiessen polygons in the Thiessen polygon distribution scheme set with centroids of the polygons as new anchor points, to generate a new anchor point distribution scheme set; generating corresponding road center line layout scheme sets by means of rectangular expansion by using the new anchor points in the new anchor point distribution scheme set as a center; and screening out a feasible road center line layout scheme set by using the rule base of the Code for Transport Planning on Urban Road, generating road network schemes from schemes in the feasible road center line layout scheme set according to the rule base of the Code for Transport Planning on Urban Road and output the road network schemes, and generating a road network scheme set; and
S5: outputting, by a man-machine interaction display module, the road network scheme set to a two-dimensional interaction display device, wherein the two-dimensional interaction display device specifically generates scheme drawings, simulates scheme effects, and displays various scheme indexes.

2. The AI-based automatic generation method for an urban road network according to claim 1, wherein in step S1, a boundary line of the planning range is a secondary trunk road, only a branch network is generated within the planning range, and the collected two-dimensional vector data within the planning range comprises information about shapes and dimensions of polygonal plots having closed outlines.

3. The AI-based automatic generation method for an urban road network according to claim 1, wherein the operation of constructing the urban branch network sample library specifically comprises collecting branch road network data of Chinese cities from the open-source data platform, and inputting the branch road network data to the geographic information platform, a boundary of a sample planning range is a secondary trunk road, a branch network is formed within the planning range, and a sample quantity is 10000.

4. The AI-based automatic generation method for an urban road network according to claim 1, wherein the operation of constructing the anchor point distribution machine learning sample library having a unified dimension specifically comprises converting the vector image of the anchor point distribution sample library to a bitmap image at a proportional scale of 1:2000, and having a resolution of 100 dpi and a dimension of 300 mm*300 mm, so as to generate the anchor point distribution machine learning sample library, wherein a sample quantity is 10000.

5. The AI-based automatic generation method for an urban road network according to claim 1, wherein the operation of performing adversarial training on the anchor point distribution model based on the generative adversarial network in step S2 specifically comprises: constructing a generative network by using white gaussian noise as input data and an anchor point automatic distribution image as output data; designing a loss function by using the anchor point automatic distribution image and an anchor point distribution machine learning sample image as the input data, so as to construct a determination network, wherein the generative network and the determination network are convolutional neural networks (CNN); and performing iterative training on the generative network and the determination network, so that the anchor automatic distribution image gradually approximates the anchor point distribution machine learning sample image.

6. The AI-based automatic generation method for an urban road network according to claim 1, wherein the operation of constructing the rule base in step S3 comprises constructing index controls according to the Code for Transport Planning on Urban Road and the specification for chamfer radius of road;
TABLE 1
Index controls for different branch network rules

| Control item | Control parameter range | |
|---|---|---|
| Branch network spacing | 150-250 | m |
| Width of boundary line of road | 12-15 | m |
| Internal chamfer of branch network | 10-15 | m |
| Chamfer of branch and external | 20-25 | m |
| secondary trunk road | | |

7. The AI-based automatic generation method for an urban road network according to claim 1, wherein in step S4, the road center line layout scheme is a corresponding road center line layout scheme generated by means of rectangular expansion by using the new anchor points as a center, and a specific operation comprises: controlling a new anchor point distribution scheme to expand in a square shape in four orthogonal directions of the new anchor point distribution scheme at a same speed by using each new anchor point as a center, when expansion sides of two adjacent anchor points come into contact with each other, or when the expansion sides all exceed the planning range, stopping expansion of the expansion sides, and still expanding other expansion sides, until all boundaries stop expanding, so as to generate rectangles of a quantity is same as a quantity of the anchor points; and arranging sides of the rectangles to form a road center line layout, and deleting sides of the rectangles that are outside the planning range or overlapping the planning range, and arranging sides of the rectangles that are inside the planning range into unique non-overlapping line segments.

8. The AI-based automatic generation method for an urban road network according to claim 1, wherein the operation of screening out the feasible road center line layout scheme set specifically comprises determining whether lengths of all road center line segments in the road center line layout scheme generated by means of rectangular expansion are within a range of 150-250 m, if no, discarding the scheme, or if yes, outputting the scheme to the feasible road center line layout scheme set.

9. The AI-based automatic generation method for an urban road network according to claim 1, wherein the operation of generating the road network scheme set specifically comprises expanding the feasible road center line layout scheme by 6-7.5 m toward two sides from a center line, to form a road boundary line having a width of 12-15 m, generating a road boundary line chamfer of 10-15 m at an intersection of internal branches, generating a road boundary line chamfer of 20-25 m at an intersection of a boundary branch and a secondary trunk road, and integrating road network schemes after the boundary line and chamfer are generated, to generate the road network scheme set.

10. The AI-based automatic generation method for an urban road network according to claim 1, wherein the simulation and the display of the scheme effects mean that an examiner selects a required road network scheme from a road network scheme library by using an operation rod and displays a scheme drawing, a scheme effect simulation diagram, and various scheme indexes on a display device having a dimension more than 55 inches and a resolution of 1920×1080; the scheme effect simulation diagram means mapping roadways and sidewalks by using modeling software on a basis of a road planar view within a planning range, wherein the roadways are mapped with asphalt textures, and the sidewalks are mapped with bricks, rendering a road network model, and combining a model render with a real scene photographed by a UAV by using image editing software, to form a scheme effect simulation diagram for displaying; and the various scheme indexes comprise a road grade, a width of a road boundary line, a road boundary line chamfer, a side length and an area of a street block formed by roads, a density of a branch network in a planning range, and a proportion of crossroad nodes to all intersection nodes.
